(19) United States
(12) Patent Application Publication
(10) Pub. No.: US 2009/0227136 A1
(43) Pub. Date: Sep. 10, 2009

(54) MOUNTING STRUCTURE FOR SURFACE MOUNTED DEVICE AND METHOD OF FIRMLY MOUNTING SURFACE MOUNTED DEVICE

(75) Inventor: Seiji TOKII, Hyogo (JP)

Correspondence Address: HAMRE, SCHUMANN, MUELLER & LARSON P.C., P.O. BOX 2902-0902, MINNEAPOLIS, MN, 55402, US

(73) Assignee: Panasonic Corporation, Osaka (JP)

(21) Appl. No.: 12/401,297

(22) Filed: Mar. 10, 2009

(30) Foreign Application Priority Data
Mar. 10, 2008 (JP) 2008-059852

(51) Int. Cl. H01R 4/28; H05K 3/34

(52) U.S. Cl. 439/345; 29/840

(57) ABSTRACT

The present invention provides a mounting structure for a surface mounted device capable of reducing sufficiently the stress applied to external joint terminal portions of a surface mounted device due to an impact caused by, for example, dropping a mobile device such as a mobile phone. A mounting structure for a surface mounted device includes: a printed circuit board; a BGA package as a surface mounted device mounted on the printed circuit board; a reinforcing member attached to the printed circuit board astride the BGA package for covering the BGA package; and a pressure pin as a pressure member passing through a top plate of the reinforcing member, being in contact with the top surface of the BGA package, and being fixed to the reinforcing member with solder.

### FIELD OF THE INVENTION

The present invention relates to a mounting structure for a surface mounted device preferable for solidly mounting a surface mounted device, such as a ball grid array (BGA) package, on a printed circuit board, and a method of firmly mounting a surface mounted device.

### DESCRIPTION OF RELATED ART

In recent years, with a trend toward a higher degree of integration and higher performance, quad flat packages (QFPs), BGA packages and the like have been used as semiconductor packages. In BGA packages, connection terminals are formed of solder balls arranged on their back sides in a grid pattern. Thus, BGA packages have the advantage of being able to be downsized while maintaining a large number of pins. However, unlike QFPs in which external terminals protrude from packaging resins toward the peripheries of the resins, BGA packages cannot reduce thermal stress, and external joint terminal portions (solder joint portions) are susceptible to thermal deformation or warpage of a printed circuit board. Therefore, a problem such as a solder crack in the external joint terminal portions occurs.

In order to solve the above problem, it has been proposed to attach a protection cover for protecting a surface mounted device such as a BGA package onto a printed circuit board, and to reduce with the protection cover the stress associated with thermal deformation or warpage of the printed circuit board applied to the external joint terminal portions (see Patent document 1, for example).

Hereinafter, a mounting structure for a BGA package proposed in Patent document 1 will be described with reference to FIG. 11. FIG. 11 is a cross-sectional view showing a conventional mounting structure for a BGA package.

As shown in FIG. 11, a conventional mounting structure 19 for a BGA package includes a BGA package 21 mounted on a printed circuit board 20, and a package protection cover 22 for reducing the stress associated with thermal deformation or warpage of the printed circuit board 20 applied to external joint terminal portions (solder joint portions) of the BGA package 21. The package protection cover 22 is attached onto the printed circuit board 20 astride the BGA package 21.

It should be noted that, in FIG. 11, reference numeral 21a denotes solder balls. The BGA package 21 is connected to electrode patterns (lands) 23 on the printed circuit board 20 due to melting of the solder balls 21a, and thereby mounted on the printed circuit board 20. Further, the package protection cover 22 is soldered to patterns (lands) 24 for attaching the cover disposed around the BGA package 21.

Patent document 1: JP H11-163494 A

For recent mobile devices such as a mobile phone, a notebook personal computer (PC) and a personal digital assistant (PDA), there has been a growing demand for robustness against a drop impact or the like.

In the case of the BGA package, the BGA package is mounted on the printed circuit board such that the BGA package itself drops toward the printed circuit board due to the melting of the solder balls. Thus, a gap appears between the BGA package and the package protection cover. When there is such a clearance above the BGA package, stress associated with a drop impact or the like applied to the external joint terminal portions (solder joint portions) cannot be reduced sufficiently even if the package protection cover is attached onto the printed circuit board.

### SUMMARY OF THE INVENTION

With the foregoing in mind, it is an object of the present invention to provide a mounting structure for a surface mounted device capable of sufficiently reducing stress applied to external joint terminal portions of the surface mounted device due to an impact caused by, for example, dropping a mobile device such as a mobile phone; and a method of firmly mounting a surface mounted device.

In order to achieve the above object, the mounting structure for a surface mounted device according to the present invention includes: a surface mounted device mounted on a printed circuit board; a reinforcing member attached onto the printed circuit board and including a top plate covering at least a periphery of a top surface of the surface mounted device; and a pressure member passing through the top plate of the reinforcing member, being in contact with the top surface of the surface mounted device, and being fixed onto the top plate with a fixing member. Here, as the fixing member, solder, a resin that softens or fluxes at a solder melting point, a thermosetting adhesive that hardens at a solder melting point or higher, or the like can be used.

According to the mounting structure for a surface mounted device of the present invention, even if a gap appears between the surface mounted device and the top plate of the reinforcing member, the surface mounted device can be solidly mounted on the printed circuit board. Thus, when the mounting structure for a surface mounted device of the present invention is incorporated into a mobile device such as a mobile phone, it is possible to reduce sufficiently the stress applied to external joint terminal portions of the surface mounted device due to an impact caused by, for example, dropping the mobile device. That is, it is possible to improve the rigidity of the surface mounted device mounted on the printed circuit board.

### DESCRIPTION OF THE PREFERRED EMBODIMENTS

In the mounting structure for a surface mounted device of the present invention, it is preferable that the pressure member is at least one of a pressure pin and a pressure bar. Further, in this case, it is preferable that a portion of the pressure member in contact with the top surface of the surface mounted device is positioned above a solder joint of a terminal of the surface mounted device and an electrode of the printed circuit board. Further, in this case, it is preferable that the number of the pressure pins that the mounting structure includes is four, and the four pressure pins are in contact with four corner portions of the top surface of the surface mounted device. According to this preferred example, forces of the pressure pins are applied uniformly to the surface mounted device. Consequently, new stress is not applied to the external joint terminal portions of the surface mounted device as a result of providing the pressure pins. Further, in this case, it is preferable that the pressure bar includes: a bar that comes into contact with the top surface of the surface mounted device; and a support pin that is coupled to the bar and passes through the top plate of the reinforcing member. Further, in this case, it is preferable that the number of the pressure bars that the mounting structure includes is four, and each of the bars of the four pressure bars is disposed along each of four sides of the top surface of the surface mounted device. According to this preferred example, similarly to the case of the pressure pins, forces of the pressure bars are applied uniformly to the surface mounted device. Consequently, new stress is not applied to the external joint terminal portions of the surface mounted device as a result of providing the pressure bars.

In the mounting structure for a surface mounted device of the present invention, it is preferable that the reinforcing member is fixed to lands disposed around the surface mounted device.

In the mounting structure for a surface mounted device of the present invention, it is preferable that a part of the reinforcing member is inserted into a positioning hole provided on the printed circuit board. According to this preferred example, the reinforcing member can be attached onto the printed circuit board at a predetermined position. Thus, pressure members such as pressure pins and pressure bars can be brought into contact with the top surface of the surface mounted device at predetermined positions. Consequently, it is possible to prevent new stress from being applied to the external joint terminal portions of the surface mounted device as a result of misalignment of the pressure members such as the pressure pins and the pressure bars.

In the mounting structure for a surface mounted device of the present invention, it is preferable that the surface mounted device is a BGA package.

A method of firmly mounting a surface mounted device includes: covering a surface mounted device mounted on a printed circuit board with a reinforcing member including a pressure member passing through a top plate of the reinforcing member and being soldered onto the top plate; and bringing the pressure member into contact with a top surface of the surface mounted device by melting the soldered portion using a heating reflow process to cause the pressure member to drop due to its own weight.

According to the method of firmly mounting a surface mounted device of the present invention, the surface mounted device easily and solidly can be mounted on the printed circuit board using a normal heating reflow process. That is, the rigidity of the surface mounted device mounted on the printed circuit board can be improved through simple steps. Conventionally, as a means for assisting to improve the rigidity, a tape or the like is attached so as to fill a gap between the surface mounted device and the top plate of the reinforcing member. According to the method of firmly mounting a surface mounted device of the present invention, it is not necessary to fill the gap and it is also not necessary to consider a variation of the gap.

According to the present invention, it is possible to reduce sufficiently the stress applied to external joint terminal portions of a surface mounted device due to an impact caused by, for example, dropping a mobile device such as a mobile phone.

### BRIEF DESCRIPTION OF THE DRAWINGS

FIG. 1 includes views showing a mounting structure for a surface mounted device according to Embodiment 1 of the present invention. FIG. 1A is a plan view, FIG. 1B is a cross-sectional view along the A-A line in FIG. 1A, and FIG. 1C is a cross-sectional view along the A-A line in FIG. 1A for describing positions of pressure pins.

FIG. 2 is a perspective view showing a reinforcing member used for the mounting structure for a surface mounted device according to Embodiment 1 of the present invention.

FIG. 3 includes cross-sectional views showing steps in a method of firmly mounting a surface mounted device according to Embodiment 1 of the present invention.

FIG. 4 is a perspective view showing another example of the reinforcing member used for the mounting structure for a surface mounted device according to Embodiment 1 of the present invention.

FIG. 5 is a perspective view showing yet another example of the reinforcing member used for the mounting structure for a surface mounted device according to Embodiment 1 of the present invention.

FIG. 6 is a cross-sectional view showing another example of the mounting structure for a surface mounted device according to Embodiment 1 of the present invention.

FIG. 7 includes perspective views showing yet another four examples of the reinforcing member used for the mounting structure for a surface mounted device according to Embodiment 1 of the present invention.

FIG. 8 includes views showing a mounting structure for a surface mounted device according to Embodiment 2 of the present invention. FIG. 8A is a plan view and FIG. 8B is a cross-sectional view along the B-B line in FIG. 8A.

FIG. 9 includes cross-sectional views showing steps in a method of firmly mounting a surface mounted device according to Embodiment 2 of the present invention.

FIG. 10 includes views showing a mounting structure for a surface mounted device according to Embodiment 3 of the present invention. FIG. 10A is a plan view, and FIG. 10B is a cross-sectional view along the C-C line in FIG. 10A.

FIG. 11 is a cross-sectional view showing a conventional mounting structure for a BGA package.

Hereinafter, the present invention will be described in detail by way of illustrative embodiments with reference to the drawings.

### EMBODIMENT 1

### A Mounting Structure for a Surface Mounted Device

First, a mounting structure for a surface mounted device according to Embodiment 1 of the present invention will be described.

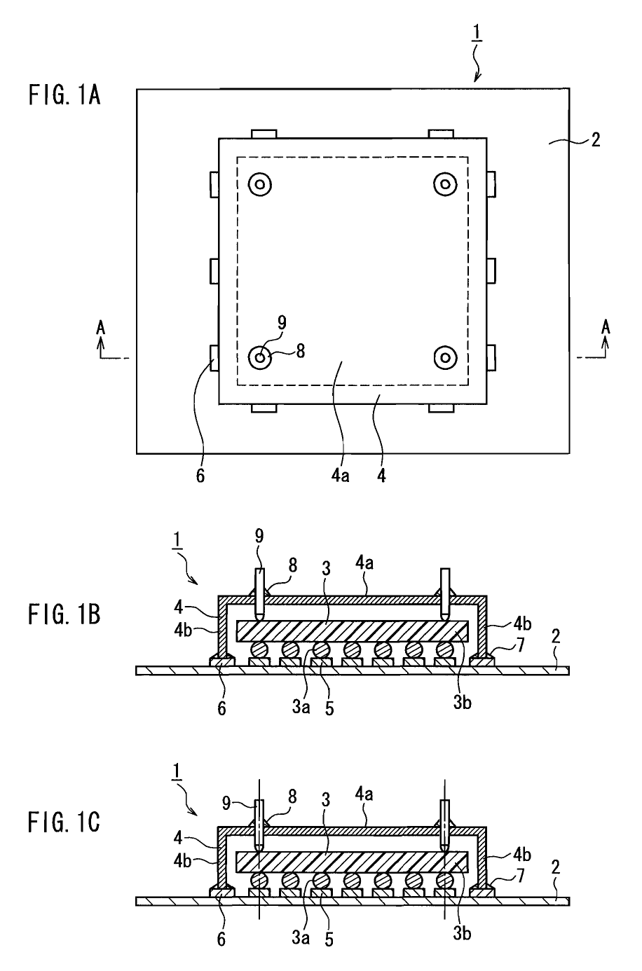

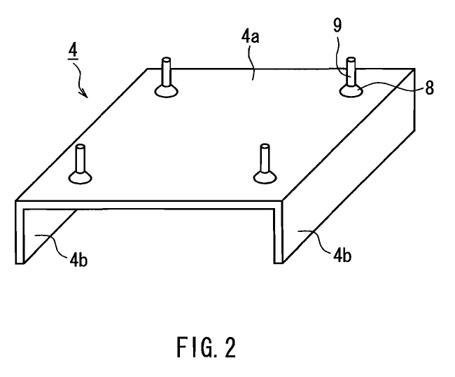

FIG. 1 includes views showing the mounting structure for a surface mounted device according to Embodiment 1 of the present invention. FIG. 1A is a plan view, FIG. 1B is a cross-sectional view along the A-A line in FIG. 1A, and FIG. 1C is a cross-sectional view along the A-A line in FIG. 1A for describing positions of pressure pins. FIG. 2 is a perspective view showing a reinforcing member used for the mounting structure for a surface mounted device according to Embodiment 1 of the present invention.

As shown in FIGS. 1 and 2, a mounting structure 1 for a surface mounted device according to the present embodiment (hereinafter also referred to as simply the “mounting structure 1”) includes a printed circuit board 2, a BGA package 3 as a surface mounted device mounted on the printed circuit board 2, and a reinforcing member 4 attached onto the printed circuit board 2 astride the BGA package 3 for covering the BGA package 3.

The reinforcing member 4 is formed of a single rectangular metal plate whose both ends are bent, and includes a square-shaped top plate 4a and rectangular leg portions 4b provided on two opposing sides of the top plate 4a, preferably at a right angle.

In FIG. 1B, reference numeral 3a denotes solder balls. The BGA package 3 is mounted on the printed circuit board 2 by connecting terminals (not shown) of a chip size package (CSP) 3b to electrode patterns (lands) 5 on the printed circuit board 2 due to melting of the solder balls 3a. Further, the reinforcing member 4 is attached onto the printed circuit board 2 by fixing the lower ends of the leg portions 4b on attachment patterns (lands) 6 (see FIG. 1A) disposed around the BGA package 3 with the solder 7.

As shown in FIGS. 1 and 2, the mounting structure 1 includes pressure pins 9 as pressure members. The pressure pins 9 pass through the top plate 4a of the reinforcing member 4, are in contact with the top surface of the BGA package 3, and are fixed to the top plate 4a of the reinforcing member 4 with solder 8 as a fixing member.

Here, the number of the pressure pins 9 that the mounting structure 1 includes is four. Each of the four pressure pins 9 is in contact with each of four corner portions of the top surface of the BGA package 3.

According to the mounting structure 1 having the configuration as described above, the BGA package 3 can be mounted solidly on the printed circuit board 2 even if a gap appears between the BGA package 3 and the top plate 4a of the reinforcing member 4. Therefore, when the mounting structure 1 is incorporated into a mobile device such as a mobile phone, it is possible to reduce sufficiently the stress applied to the solder joint portions (external joint terminal portions) of the BGA package 3 due to an impact caused by, for example, dropping the mobile device. That is, it is possible to improve the rigidity of the BGA package 3 mounted on the printed circuit board 2.

Further, the number of the pressure pins 9 that the mounting structure 1 according to the present embodiment includes is four and each of the four pressure pins 9 is brought into contact with each of the four corner portions of the top surface of the BGA package 3. Thus, forces of the pressure pins 9 are applied uniformly to the BGA package 3. Consequently, new stress is not applied to the solder joint portions (external joint terminal portions) of the BGA package 3 as a result of providing the pressure pins 9.

Further, as shown in FIG. 1C, the portions of the pressure pins 9 in contact with the top surface of the BGA package 3 are positioned above the solder joints of terminals of the CSP 3b and the electrode patterns 5 on the printed circuit board 2. That is, the mounting structure 1 according to the present embodiment includes the pressure pins 9, each of them being disposed on a vertical line that passes through the center of a terminal of the CSP 3b and the electrode pattern 5.

In the mounting structure 1 according to the present embodiment, the pressure pins 9 as pressure members are fixed onto the top plate 4a of the reinforcing member 4 with the solder 8. However, the mounting structure 1 is not necessarily limited to such a configuration. For example, the pressure pins 9 as pressure members may be adhered and fixed onto the top plate 4a of the reinforcing member 4 with, for example, a resin that softens or fluxes at a melting point of the solder balls 3a or with a thermosetting adhesive that hardens at the melting point of the solder balls 3a or higher.

### A Method of Firmly Mounting a Surface Mounted Device

Next, a method of firmly mounting a surface mounted device according to the present embodiment will be described.

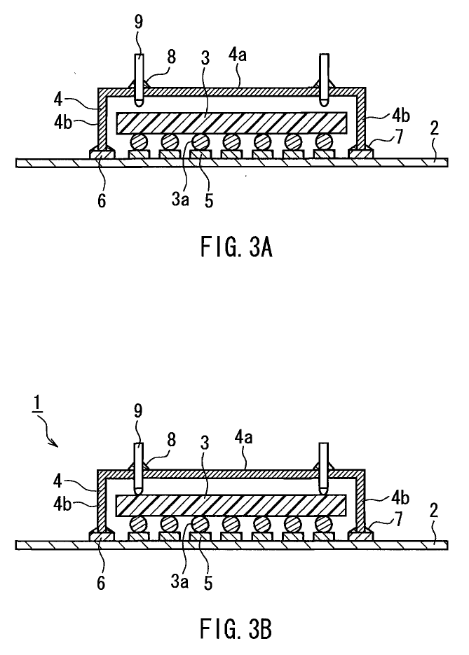

FIG. 3 includes cross-sectional views showing steps in the method of firmly mounting a surface mounted device according to Embodiment 1 of the present invention.

As shown in FIG. 3A, the BGA package 3 as a surface mounted device mounted on the printed circuit board 2 is covered with the reinforcing member 4, and the lower ends of the leg portions 4b of the reinforcing member 4 are fixed to the attachment patterns (lands) 6 disposed around the BGA package 3 with the solder 7. Here, the reinforcing member 4 includes the four pressure pins 9. The pressure pins 9 are inserted into through holes provided on the top plate 4a, which are sized to permit some play, and are fixed to the reinforcing member 4 with the solder 8 in advance (see FIG. 2). At this point, the lower ends of the pressure pins 9 are not in contact with the top surface of the BGA package 3.

Next, as shown in FIG. 3B, the solder 8 that fixes the pressure pins 9 to the reinforcing member 4 is melted using a heating reflow process, and thereby the pressure pins 9 drop toward the BGA package 3 under their own weight. The pressure pins 9 stop in a state where the lower ends of the pressure pins 9 are in contact with the top surface of the BGA package 3. In this state, the solder 8 is cooled and hardened, thereby refixing the pressure pins 4 to the reinforcing member 4. As a result, the BGA package 3 is mounted solidly on the printed circuit board 2.

According to the method of firmly mounting a surface mounted device including the steps as described above, the BGA package 3 can be mounted easily and solidly on the printed circuit board 2 using a normal heating reflow process. That is, the rigidity of the BGA package 3 to be mounted on the printed circuit board 2 can be improved through simple steps.

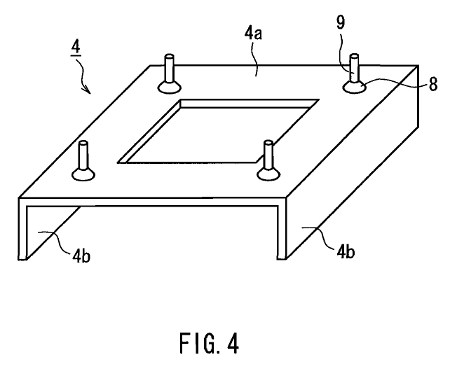

In the present embodiment, the reinforcing member 4 having the square-shaped top plate 4a is used. It should be noted, however, that the top plate 4a of the reinforcing member 4 may have an opening at its center portion as shown in FIG. 4. That is, the reinforcing member only needs to have a top plate that covers at least the periphery of the top surface of the BGA package (surface mounted device) 3. Further, the shape of the top plate 4a is not limited to square and can be changed appropriately in accordance with the shape of the BGA package (surface mounted device) 3.

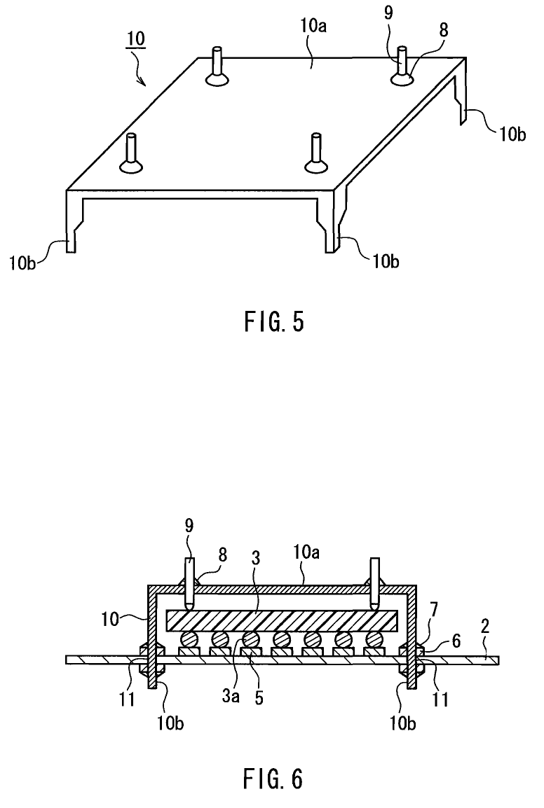

Further, by using a reinforcing member 10 including a square-shaped top plate 10a having leg portions 10b at its respective corners as shown in FIG. 5, inserting the lower ends of the leg portions 10b of the reinforcing member 10 into positioning holes 11 that pass through the attachment patterns (lands) 6 on the printed circuit board 2, and fixing the lower ends of the leg portions 10b onto the printed circuit board 2 with the solder 7 as shown in FIG. 6, the reinforcing member 10 can be attached onto the printed circuit board 2 at a predetermined position. Thus, the pressure pins 9 can be brought into contact with the top surface of the BGA package 3 at predetermined positions. Consequently, it is possible to prevent new stress from being applied to the solder joint portions (external joint terminal portions) of the BGA package 3 as a result of misalignment of the pressure pins 9. Similarly to the reinforcing member 4 shown in FIG. 4, in the reinforcing member 10 shown in FIG. 5, the top plate 10a may have an opening at its center portion. Further, the shape of the top plate 10a also is not limited to square.

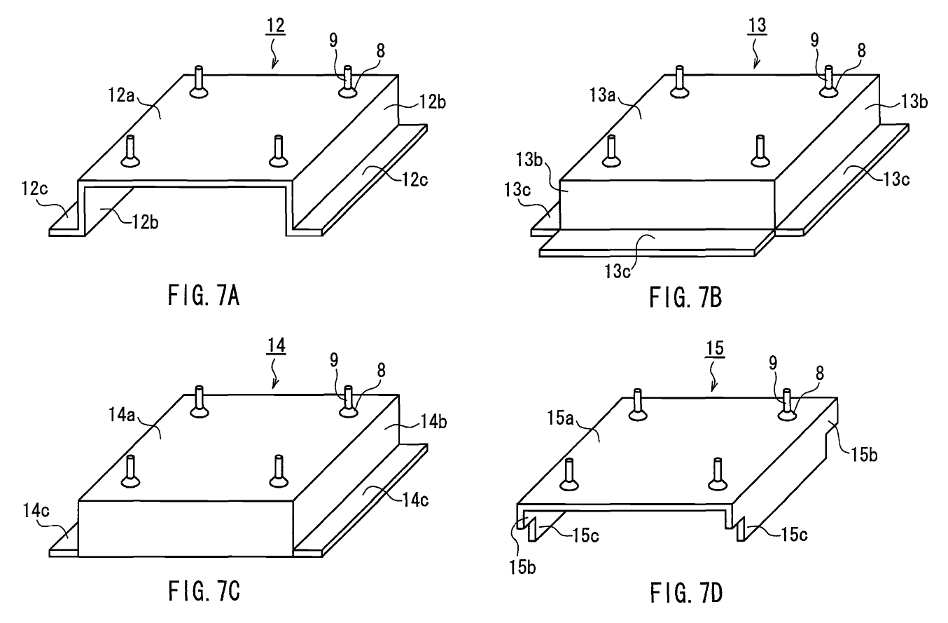

As the reinforcing member, those with various shapes can be used in addition to the reinforcing members 4 and 10 having the shapes described above (see FIGS. 2, 4 and 5). FIG. 7 shows four other examples of the reinforcing member.

A reinforcing member 12 shown in FIG. 7A includes: a square-shaped top plate 12a; rectangular leg portions 12b provided respectively on two opposing sides of the top plate 12a at a right angle; and rectangular attachment portions 12c provided on the lower ends of the respective leg portions 12b at a right angle (in parallel with the top plate 12a). By using the reinforcing member 12 including the attachment portions 12c having a large contact area with the printed circuit board 2, the reinforcing member can be attached to the printed circuit board stably.

A reinforcing member 13 shown in FIG. 7B includes: a square-shaped top plate 13a; rectangular leg portions 13b provided on the four sides of the top plate 13a at a right angle; and attachment portions 13c provided on the lower ends of the respective leg portions 13b at a right angle (in parallel with the top plate 13a).

In a reinforcing member 14 shown in FIG. 7C, unlike the reinforcing member 13 shown in FIG. 7B, attachment portions 14c are provided only on two opposing leg portions 14b. It should be noted that reference numeral 14a denotes a top plate.

A reinforcing member 15 shown in FIG. 7D includes: a square-shaped top plate 15a; and substantially rectangular leg portions 15b provided on two opposing sides of the top plate 15a at the right angle. Each of the leg portions 15b is provided with an attachment piece 15c that is to be inserted into a slit-shaped positioning hole formed on the printed circuit board 2.

Similarly to the reinforcing member 4 shown in FIG. 4, in the reinforcing members 12 to 15 shown in FIG. 7, the top plates 12a to 15a may include an opening at their center portions. Further, the shape of the top plates 12a to 15a is not limited to square.

Further, the number of the pressure pins 9 used in the present embodiment is four. However, the number of the pressure pins 9 is not limited to four. For example, one pressure pin that comes into contact with the top surface of the BGA package (surface mounted device) 3 at the center, or a large number of pressure pins that come into contact with the periphery of the top surface of the BGA package (surface mounted device) 3 may be used.

### EMBODIMENT 2

### A Mounting Structure for a Surface Mounted Device

First, a mounting structure for a surface mounted device according to Embodiment 2 of the present invention will be described.

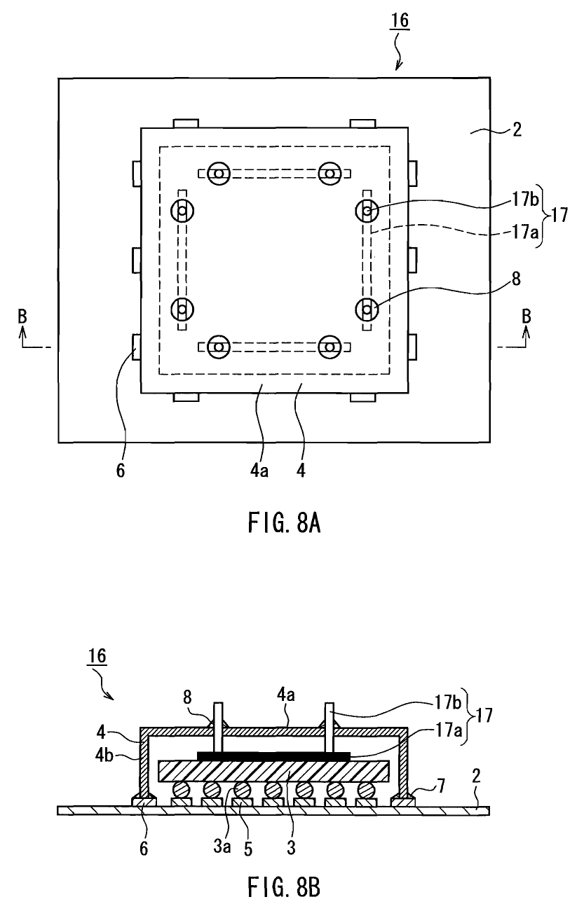

FIG. 8 includes views showing the mounting structure for a surface mounted device according to Embodiment 2 of the present invention. FIG. 8A is a plan view, and FIG. 8B is a cross-sectional view along the B-B line in FIG. 8A.

The mounting structure according to the present embodiment is different from the mounting structure 1 according to Embodiment 1 (see FIG. 1) in that pressure bars are used as pressure members instead of the pressure pins 9. Thus, in the present embodiment, the pressure bars as pressure members mainly will be described, and the descriptions of other components will not be repeated. Also in the present embodiment, the reinforcing member 4 having the shape shown in FIG. 2 is used. However, reinforcing members with various shapes, such as those shown in FIGS. 4, 5, and 7 can be used also, for example.

As shown in FIG. 8, the mounting structure 16 according to the present embodiment includes pressure bars 17. Each of the pressure bars 17 includes: a bar 17a that comes into contact with the top surface of the BGA package 3; and two support pins 17b that pass through the top plate 4a of the reinforcing member 4 in a state of being coupled to the bar 17a, and are fixed onto the top plate 4a of the reinforcing member 4 with the solder 8 as a fixing member.

The number of the pressure bars 17 that the mounting structure 16 includes is four. Each of the bars 17a of the four pressure bars 17 is disposed along each of the four sides of the top surface of the BGA package 3.

According to the mounting structure 16 having the configuration as described above, the BGA package 3 can be mounted solidly on the printed circuit board 2 even if a gap appears between the BGA package 3 and the top plate 4a of the reinforcing member 4. Therefore, when the mounting structure 16 is incorporated into a mobile device such as a mobile phone, it is possible to reduce sufficiently the stress applied to the solder joint portions (external joint terminal portions) of the BGA package 3 due to an impact caused by, for example, dropping the mobile device. That is, it is possible to improve the rigidity of the BGA package 3 mounted on the printed circuit board 2.

Further, the number of the pressure bars 17 that the mounting structure 16 according to the present embodiment includes is four, and each of the bars 17a of the four pressure bars 17 is disposed along each of the four sides of the top surface of the BGA package 3. Thus, forces of the bars 17a are applied uniformly to the BGA package 3. Consequently, new stress is not applied to the solder joint portions (external joint terminal portions) of the BGA package 3 as a result of providing the pressure bars 17.

In the mounting structure 16 according to the present embodiment, the support pins 17b of the pressure bars 17 as pressure members are fixed to the reinforcing member 4 with the solder 8. However, the mounting structure 16 is not limited to such a configuration. For example, the support pins 17b of the pressure bars 17 as pressure members may be adhered and fixed onto the top plate 4a of the reinforcing member 4 with, for example, a resin that softens or fluxes at the melting point of the solder balls 3a or with a thermosetting adhesive that hardens at the melting point of the solder balls 3a or higher.

### A Method of Firmly Mounting a Surface Mounted Device

Next, a method of firmly mounting a surface mounted device according to the present embodiment will be described.

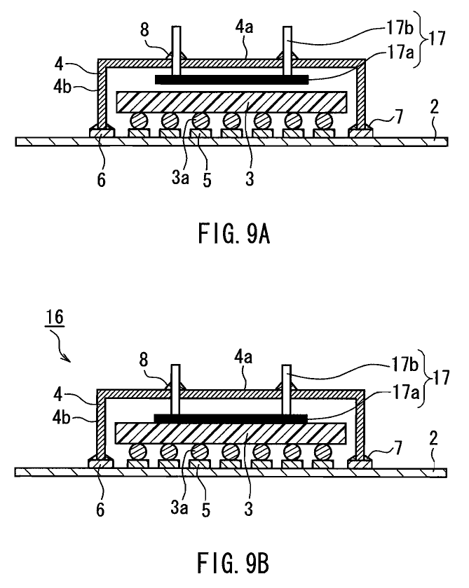

FIG. 9 includes cross-sectional views showing steps in the method of firmly mounting a surface mounted device according to Embodiment 2 of the present invention.

First, as shown in FIG. 9A, the BGA package 3 as a surface mounted device mounted on the printed circuit board 2 is covered with the reinforcing member 4, and the lower ends of the leg portions 4b of the reinforcing member 4 are fixed to the attachment patterns (lands) 6 disposed around the BGA package 3 with the solder 7. Here, the reinforcing member 4 includes the four pressure bars 17 (see FIG. 8A). Each of the pressure bars 17 is composed of: the two support pins 17b that are inserted into the through holes formed on the top plate 4a of the reinforcing member 4 with play, and are fixed to the reinforcing member 4 with the solder 8 in advance; and the bar 17a that is coupled to the lower ends of the two support pins 17b. At this point, none of the bars 17a of the four pressure bars 17 is in contact with the top surface of the BGA package 3.

Next, as shown in FIG. 9B, the solder 8 that fixes the support pins 17b of each of the pressure bars 17a to the reinforcing member 4 is melted using a heating reflow process, thereby each of the pressure bars 17 drops toward the BGA package 3 under its own weight. Each of the pressure bars 17 stops in a state where the bars 17 are in contact with the top surface of the BGA package 3. In this state, the solder 8 is cooled and hardened, thereby refixing the support pins 17b of each of the pressure bars 17 to the reinforcing member 4. As a result, the BGA package 3 is mounted solidly on the printed circuit 2.

According to the method of firmly mounting a surface mounted device including the steps as described above, the BGA package 3 can be mounted easily and solidly on the printed circuit board 2 using a normal heating reflow process. That is, the rigidity of the BGA package 3 to be mounted on the printed circuit board 2 can be improved through simple steps.

The number of the pressure bars 17 used in the present embodiment is four. However, the number of the pressure bars 17 is not limited to four. For example, only one pressure bar including a bar that pass through the center of the top surface of the BGA package (surface mounted device) 3 and disposed so as to be symmetrical on the top surface. Further, a large number of pressure bars including a bar disposed on the top surface of the BGA package (surface mounted device) 3 in parallel with one side of the BGA package (surface mounted device) 3 may be used.

### EMBODIMENT 3

Next, a mounting structure for a surface mounted device according to Embodiment 3 of the present invention will be described.

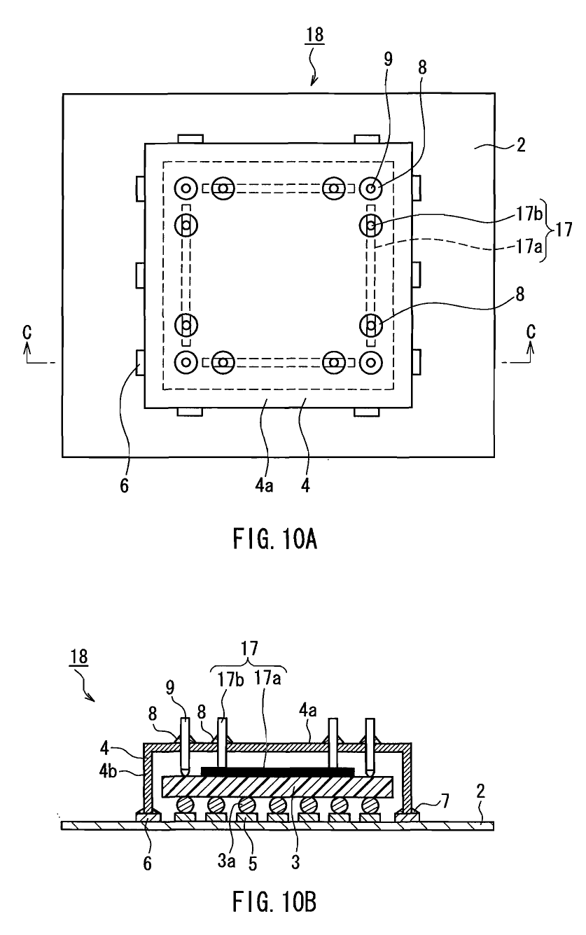

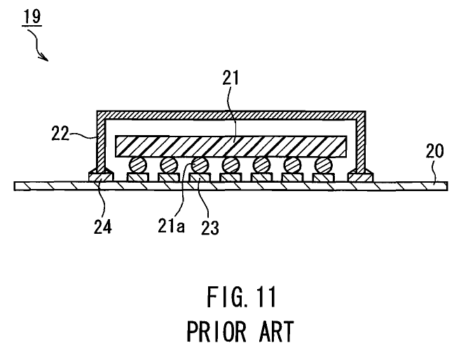

FIG. 10 includes views showing the mounting structure for a surface mounted device according to Embodiment 3 of the present invention. FIG. 10A is a plan view, and FIG. 10B is a cross-sectional view along the C-C line in FIG. 10A.

The mounting structure according to the present embodiment is different from the mounting structures 1 and 16 according to Embodiments 1 and 2 respectively (see FIGS. 1 and 8) in that both pressure pins and pressure bars are used as pressure members. Thus, in the present embodiment, the pressure members mainly are described, and the descriptions of other components will not be repeated. Also in the present embodiment, the reinforcing member 4 with the shape shown in FIG. 2 is used. However, reinforcing members with various shapes such as those shown in FIGS. 4, 5, and 7 also can be used, for example.

As shown in FIG. 10, the mounting structure 18 according to the present embodiment includes the pressure pins 9 and the pressure bars 17. Here, the pressure pins 9 pass through the top plate 4a of the reinforcing member 4, are in contact with the top surface of the BGA package 3, and are fixed onto the top plate 4a of the reinforcing member 4 with the solder 8 as a fixing member. The number of the pressure pins 9 that the mounting structure 18 includes is four, so that they can come into contact with the four respective corner portions of the top surface of the BGA package 3. Further, each of the pressure bars 17 is composed of: the bar 17a that comes into contact with the top surface of the BGA package 3; and the two support pins 17b that are coupled to the bar 17a, pass through the top plate 4a of the reinforcing member 4, and are fixed onto the top plate 4a of the reinforcing member 4 with the solder 8 as a fixing member. The number of the pressure bars 17a that the mounting structure 18 includes is four, so that they can be disposed along the four sides of the top surface of the BGA package 3 respectively.

According to the mounting structure 18 having the configuration as described above, since the mounting structure 18 includes both the pressure pins 9 and the pressure bars 17, it is possible to mount the BGA package 3 on the printed circuit board 2 more solidly. Therefore, when the mounting structure 18 is incorporated into a mobile device such as a mobile phone, it is possible to reduce sufficiently the stress applied to the solder joint portions (external joint terminal portions) of the BGA package 3 due to an impact caused by, for example, dropping the mobile device. That is, it is possible to improve the rigidity of the BGA package 3 mounted on the printed circuit board 2 further.

Since a method of firmly mounting a surface mounted device according to the present embodiment is similar to those according to Embodiments 1 and 2, the descriptions will not be repeated.

Though at least one of the pressure pin 9 and the pressure bar 17 is used as the pressure member in the above embodiments, the pressure member is not limited to a pressure pin or a pressure bar. For example, the pressure member can be formed of a plate that comes into contact with the top surface of the surface mounted device and a plurality of support pins that are coupled to the plate and pass through the top plate of the reinforcing member.

Though the above embodiments refer to an example of using the BGA package 3 as a surface mounted device, the surface mounted device is not limited to a BGA package. For example, the present invention can also be used as a mounting structure for and a method of firmly mounting a land grid array (LGA) package or the like.

As described above, according to the present invention, even if a gap appears between a surface mounted device and a top plate of a reinforcing member, the surface mounted device can be solidly mounted on the printed circuit board. Accordingly, the present invention is useful as a mounting structure for a surface mounted device incorporated into a mobile device such as a mobile phone to which a demand for robustness against a drop impact or the like has been growing.

The invention may be embodied in other forms without departing from the spirit of essential characteristics thereof. The embodiments disclosed in this application are to be considered in all respects as illustrative and not limiting. The scope of the invention is indicated by the appended claims rather than by the foregoing description, and all changes that come within the meaning and range of equivalency of the claims are intended to be embraced therein.

What is claimed is:

1. A mounting structure for a surface mounted device, comprising:
a surface mounted device mounted on a printed circuit board;
a reinforcing member attached onto the printed circuit board and including a top plate covering at least a periphery of a top surface of the surface mounted device; and
a pressure member passing through the top plate of the reinforcing member, being in contact with the top surface of the surface mounted device, and being fixed onto the top plate with a fixing member.

2. The mounting structure for a surface mounted device according to claim 1, wherein the pressure member is at least one of a pressure pin and a pressure bar.

3. The mounting structure for a surface mounted device according to claim 2, wherein a portion of the pressure member in contact with the top surface of the surface mounted device is positioned above a solder joint of a terminal of the surface mounted device and an electrode of the printed circuit board.

4. The mounting structure for a surface mounted device according to claim 2, wherein the number of the pressure pin that the mounting structure includes is four and the four pressure pins are in contact with four corner portions of the top surface of the surface mounted device.

5. The mounting structure for a surface mounted device according to claim 2, wherein the pressure bar includes: a bar that comes into contact with the top surface of the surface mounted device; and a support pin that is coupled to the bar and passes through the top plate of the reinforcing member.

6. The mounting structure for a surface mounted device according to claim 5, wherein the number of the pressure bar that the mounting structure includes is four, and the bars of the four pressure bars are disposed respectively along four sides of the top surface of the surface mounted device.

7. The mounting structure for a surface mounted device according to claim 1, wherein the reinforcing member is fixed to lands disposed around the surface mounted device.

8. The mounting structure for a surface mounted device according to claim 1, wherein a part of the reinforcing member is inserted into a positioning hole provided on the printed circuit board.

9. The mounting structure for a surface mounted device according to claim 1, wherein the surface mounted device is a ball grid allay package.

10. A method of firmly mounting a surface mounted device, comprising:
covering a surface mounted device mounted on a printed circuit board with a reinforcing member including a pressure member passing through a top plate of the reinforcing member and being soldered onto the top plate; and
bringing the pressure member into contact with a top surface of the surface mounted device by melting the soldered portion using a heating reflow process to cause the pressure member to drop under its own weight.
